(19) United States
(12) Patent Application Publication
(10) Pub. No.: US 2025/0165689 A1
(43) Pub. Date: May 22, 2025

(54) ADAPTIVE TEST GENERATION FOR FUNCTIONAL COVERAGE CLOSURE

(71) Applicant: Google LLC, Mountain View, CA (US)

(72) Inventors: Azade Nova, San Jose, CA (US); Qijing Huang, Berkeley, CA (US); Hamid Shojaei, San Jose, CA (US); Azalia Mirhoseini, Mountain View, CA (US); Chian-min Richard Ho, Palo Alto, CA (US)

(21) Appl. No.: 18/840,532

(22) PCT Filed: Feb. 28, 2023
(86) PCT No.: PCT/US2023/014167

§ 371 Date: Aug. 22, 2024

Related U.S. Application Data
(60) Provisional application No. 63/315,030, filed on Feb. 28, 2022.

(51) Int. Cl. G06F 30/3308

(52) U.S. Cl. CPC G06F 30/3308

(57) ABSTRACT

Methods, systems, and apparatus for adaptively generating test stimuli for testing a hardware design for an integrated circuit. In one aspect, a system comprises one or more computers configured to obtain graph data representing a coverage dependency graph associated with a hardware design for an integrated circuit. At each of a plurality of simulation cycles, the one or more computers obtain a set of coverage statistics as of the simulation cycle and update respective distribution constraints for one or more random variables in a set of random variables using the coverage dependency graph and the coverage statistics. After the updating, the one or more computers generate one or more test stimuli by, for each test stimulus, sampling a respective value for each of the random variables based on the respective distribution constraints. The one or more computers simulate a performance of the integrated circuit for each of the test stimuli.

### CROSS-REFERENCE TO RELATED APPLICATIONS

This application claims the benefit of priority to U.S. Provisional Application Ser. No. 63/315,030, filed Feb. 28, 2022. The content of the prior application is incorporated herein by reference in its entirety.

### BACKGROUND

This specification generally relates to performing design verification of integrated circuit designs.

As part of verifying the design of an integrated circuit, some systems perform coverage-driven test generation to generate test stimuli for design verification of the integrated circuit design.

### SUMMARY

This specification describes a system implemented as computer programs on one or more computers in one or more locations that adaptively generates test stimuli for testing a hardware design for an integrated circuit. In particular, the system generates the test stimuli to improve the coverage of the design verification process.

According to a first aspect there is provided a method performed by one or more computers. The method includes obtaining graph data that represents a coverage dependency graph associated with a hardware design for an integrated circuit.

At each of multiple simulation cycles, the one or more computers can obtain a set of coverage statistics as of the simulation cycle. The one or more computers then updates respective distribution constraints for one or more random variables of a set of random variables using the coverage dependency graph and the coverage statistics. After the updating, the one or more computers generate one or more test stimuli by, for each test stimulus, sampling a respective value for each of the random variables in the set of random variables based on the respective distribution constraints. The one or more computers then simulates a performance of the integrated circuit for each of the test stimuli.

Particular embodiments of the subject matter described in this specification can be implemented so as to realize one or more of the following advantages.

Coverage-driven test generation is a widely used approach to accelerate design verification of a hardware design for fabricating an integrated circuit. Coverage-driven test generation includes performing multiple simulation cycles with test stimuli to simulate different test-cases of the hardware design. For each simulation cycle, a verification expert can update the test stimuli to increase the coverage of the test-cases, e.g., increase how well the test stimuli cover the test-cases. However, existing coverage-driven test generation methods rely on verification experts to extrapolate coverage-to-input relationships or use costly data driven techniques to learn these dependencies, both of which introduce significant overhead to the verification process.

This specification describes a low-overhead framework that automatically extracts the coverage dependency graph associated with a design and leverages the dependency information for adaptive test stimuli generation. The test generation is performed by a new mechanism that adaptively changes the distribution of the random input stimuli to exercise the design more comprehensively towards higher coverage. The described techniques result in an automatic distribution assignment strategy that is optimal for coverage closure (for example, achieving 100% coverage) and significantly speed up the coverage convergence.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a block diagram of an example conventional system for testing a hardware design of an integrated circuit.

FIG. 2 is a block diagram of an example system for adaptive test stimuli generation.

FIG. 3 is a diagram of an example system for generating updated test stimuli.

FIG. 4 is a diagram of an example system for generating a coverage dependency graph (CDG) to adaptively update test stimuli.

FIG. 5 is a flow diagram of an example process for adaptively updating test stimuli to test a hardware design of an integrated circuit.

Like reference numbers and designations in the various drawings indicate like elements.

### DETAILED DESCRIPTION

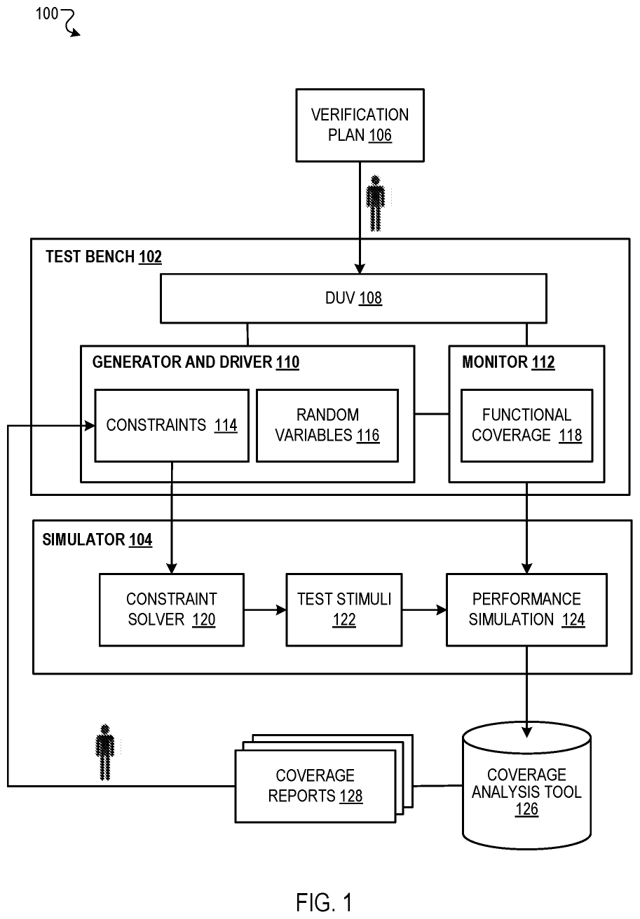

FIG. 1 shows an example system 100 for testing a hardware design of an integrated circuit. The system 100 is an example of a system in which the systems, components, and techniques described below are implemented.

The system 100 is an example of a verification system that includes a test bench 102 and a simulator 104. The system 100 uses the test bench 102 and the simulator 104 to simulate the performance of a hardware design (e.g., a design under verification (DUV) 108).

Design verification is a crucial step in chip development (e.g., integrated circuit designs) to determine the correctness of a hardware design. A hardware design includes a design of computer hardware components, such as circuit boards, microchips, and hardware schematics.

A verification system can simulate the verification performance of a hardware design to determine whether to fabricate an integrated circuit of the hardware design. The verification system can determine to accept the hardware design if the hardware design meets certain design criteria based on multiple simulations of the verification performance.

If the hardware design is accepted, the verification system can use conventional fabrication techniques to fabricate an integrated circuit that includes the accepted hardware design.

Alternatively, the verification system can reject the hardware design if the hardware design fails to meet the certain design criteria.

Additionally, the verification system can update the design verification to more efficiently determine whether to accept the hardware design based on a coverage of the design verification. The coverage of the hardware design measures the quality of the simulation of the hardware design, e.g., how well the design verification covers certain test-cases to test the performance of the hardware design.

In conventional approaches, the system 100 verifies the DUV 108 by generating test stimuli to simulate the performance of the DUV 108 through constrained random verification (CRV).

Generally, CRV involves the system 100 using a test bench to simulate the DUV 108 at the code level. The test bench 102 runs multiple simulations by running different code (e.g., hardware description language (HDL) code) at each simulation. The code operates as a random input stimulus for the DUV 108 that tests the coverage of the DUV 108. The test bench 102 can generate a random input stimulus using constraints and random variables. The random input stimulus drives the simulation of the DUV 108 performed by a simulator 104.

The system 100 then generates test stimuli from the random input stimulus. The system 100 can determine the coverage of the design verification (e.g., the testing simulation of the DUV 108) by generating information regarding the coverage of the test stimuli. The system 100 can generate the information of the coverage of the design verification by running a simulation using the test stimuli and generating coverage statistics based on the simulation. The “coverage” of a set of test stimuli generally measures what percentage of the stimuli have been tested as part of the design verification.

Specifically, the system 100 obtains a verification plan 106 from a verification expert. The verification expert can design the test bench 102 based on the verification plan 106. The verification plan 106 includes information related to functional coverage 118 that guide the generation of the test stimuli. Functional coverage 118 includes definitions of test-cases that must be tested by the test stimuli as part of the overall coverage of the design verification.

The test bench 102 includes a generator and driver 110 and a monitor 112.

The test bench 102 generates multiple random input stimuli and sends the random input stimuli to the DUV 108 using the generator and driver 110.

The test bench 102 generates the random input stimuli using constraints 114 and random variables 116. The random variables 116 are design variables whose values are stochastically generated subject to user-specified constraints (e.g., constraints 212). The constraints 114 can be legalization constraints, ordering constraints, or distribution constraints.

Legalization constraints impose user-specified valid value ranges on random variables 116. Ordering constraints can specify the ordering of constraint solving for different random variables 116. Distribution constrains can bias the uniform value distribution over a random variable 116 to a user-defined distribution. For example, a verification expert can assign high weights to values in a distribution constraint range, such that the values in the distribution constraint range are assigned more often to a random variable 116.

Thus, the test bench 102 can use the constraints 114 to enforce ranges and distributions of the values of the random variables 214 to generate the random stimulus.

After the test bench 102 sends the random input stimuli to the DUV 108, the test bench 102 runs a simulation of the DUV 108 at the code level, and the DUV 108 generates a design output.

The monitor 112 verifies the design output (e.g., actual output) of the DUV 108 against the modeled output (e.g., theoretical output) of the DUV 108 using a checker. The monitor 112 includes the definitions from the verification plan 106 in the form of functional coverage groups included in the functional coverage 118. The functional coverage groups (e.g., covergroups) are test-cases that must be tested by the simulator 104 to verify the coverage of the design verification.

To run the simulation, the simulator 104 obtains the constraints 114 and the functional coverage 118 from the test bench 102.

The simulator 104 includes a constraint solver 120.

The simulator 104 processes the constraints 114 to generate test stimuli 122 using the constraint solver 120. The simulator 104 runs the constraint solver 120 to generate the test stimuli 122 by selecting the random input stimuli that satisfy the constraints 114. The simulator 104 then uses the test stimuli 122 and the functional coverage 118 to run a performance simulation 124 of the DUV 108.

The performance simulation 124 can be a register-transfer level (RTL) simulation with the test stimuli 122 as input to test the DUV 108, where the RTL simulation reports the verification coverage of the test stimuli 122.

After simulating the DUV 108 with the test stimuli 122, a coverage analysis tool 126 measures the distribution of the test stimuli 122 in verifying the test-cases. For example, the coverage analysis tool 126 generates coverage reports 128 (e.g., coverage statistics) that summarize the coverage of the distribution (e.g., a summary of how well the test stimuli 122 cover different test-cases of the DUV 108).

The system 100 can perform multiple simulation cycles, and the system 100 can implement coverage-directed test generation at each simulation cycle to update the constraints 114 in order to improve the coverage of the test stimuli 122.

In some examples, such as model-based coverage-directed test generation, the test bench 102 uses an external model of the DUV 108 to generate test-cases targeting desired coverage events.

In this case, verification experts obtain statistics of unexplored coverage events from the coverage reports 128 generated by the coverage analysis tool 126. A verification expert can create an external model to direct the simulation towards the uncovered events of the DUV 108. However, the manual verification and model creation by verification experts increases verification overhead. Additionally, the external model of the DUV is generally an abstract finite-state machine (FSM), which suffers from scalability issues on complex designs.

Alternatively, the system 100 can implement data-driven coverage-driven test generation techniques, in which the system 100 determines the relationship between coverage and the test stimuli 122 directly from the observations gathered from the performance simulation 124. However, these techniques either rely on a significant amount of domain knowledge in the system 100, or they require a considerable amount of simulations to obtain enough data for determining the relationship between the coverage and the test stimuli 122.

Thus, current coverage-driven test generation techniques can require a large amount of human effort in updating the test stimuli 122 and can increase verification overhead due to scalability issues and the large amount of data needed to extrapolate the dependencies from the simulation.

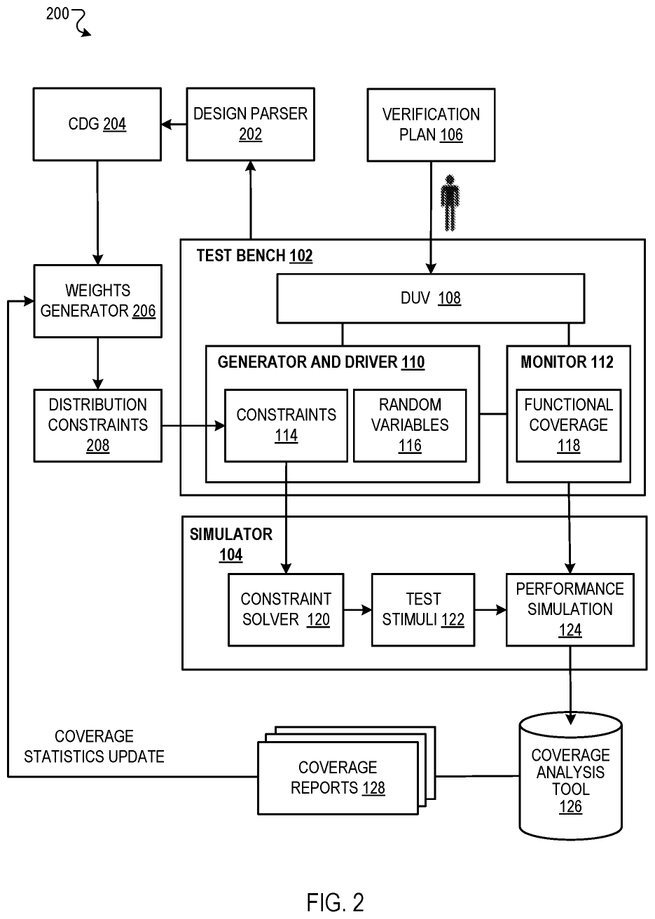

This specification describes a system that improves verification efficiency with minimal verification overhead by adaptively updating the test stimuli 122. The system uses the distribution constraints included in the constraints 114 and the functional coverage 118 to leverage a coverage dependency graph (CDG) for updating the test stimuli 122, as described in further detail below with reference to FIGS. 2, 3, and 4.

FIG. 2 shows an example system 200 for adaptive test stimuli generation. The system 200 is an example of a system in which the systems, components, and techniques described below are implemented. For convenience, the system 200 will be described as being implemented by a system of one or more computers located in one or more locations. For example, a system, e.g., the system 100 of FIG. 1, appropriately programmed in accordance with this specification, can implement the system 200.

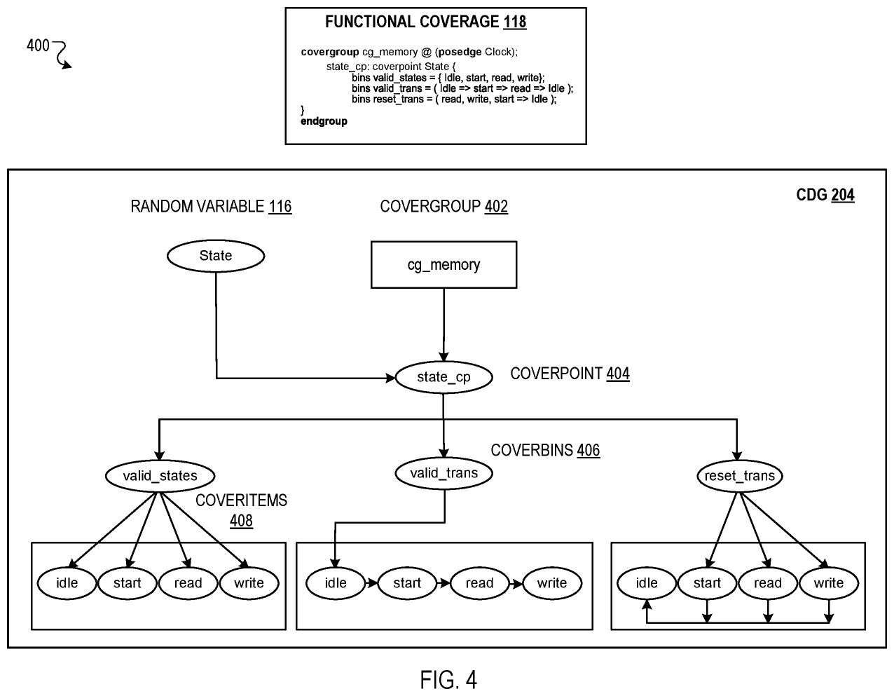

Unlike conventional approaches, the system 200 leverages a CDG to update the test stimuli 122 and to improve the overall coverage of the design verification. A CDG is a graph derived from graph data extracted from the functional coverage 118 of the verification plan 106. The CDG maps dependencies of covergroups and random variables 116, as described in further detail with reference to FIG. 4.

In this implementation, the system 200 obtains a CDG 204 from the test bench 102. The system 200 uses the CDG 204 to guide the test stimuli generation of the simulator 104. The system 200 guides the test stimuli generation by adaptively updating distribution constraints of the constraints 114 based on the dependency information from the CDG 204.

In addition to the components described above with reference to FIG. 1, the system 200 also includes a design parser 202 and a weight generator 206.

For each simulation cycle of multiple simulation cycles, the system 200 runs a simulation of the DUV 108 using the test bench 102 and the simulator 104. The system 200 then updates a set of coverage statistics after performing the simulation cycle. The coverage statistics include the information from the coverage reports 128.

The system 200 then uses the design parser 202 to generate the CDG 204. The design parser 202 leverages the functional coverage 118 parsed from design tools and generates the CDG 204 based on automatically extracted information of the covergroups included in the functional coverage 118.

The system 200 then uses the weights generator 206 to update the weights of respective distribution constraints 208 associated with the random variables 116. The weights generator 206 increases the weights of respective distribution constraints 208 such that the constraints will be assigned more often to a particular random variable 116. Thus, the weights generator 206 determines to update the values of the weights based on how often the values of the range of a respective distribution constraint must be applied to a random variable 116 to increase coverage.

The weights generator 206 adaptively determines the values of the weights of the distribution constraints 208 to increase coverage by performing a maximum likelihood estimation (MLE) using the information from the coverage statistics and the CDG 204, which will be described in further detail with reference to FIG. 4.

The system 200 then uses the simulator 104 to generate updated test stimuli 122 by processing the updated distribution constraints 208 as part of the constraints 114. The simulator 104 uses the constraint solver to select random input stimuli that satisfy the constraints 114, including selecting random input stimuli based on the weights of the updated distribution constraints 208. For example, the weights of the updated distribution constraints 208 bias the distribution of the test stimuli 122, such that values in a distribution constraint range with higher weights are assigned more often to assigned to a random variable 116 corresponding to the test stimuli 122.

The simulator 104 then uses the test stimuli 122 and the functional coverage 118 to run a performance simulation 124 of the DUV 108.

Thus, the system 200 can increase the efficiency of updating the test stimuli 122 by leveraging the predefined functional coverage 118 in the test bench 102 in order to update the weights of the distribution constraints 208, which further improves the verification quality by increasing the coverage of the test stimuli 122.

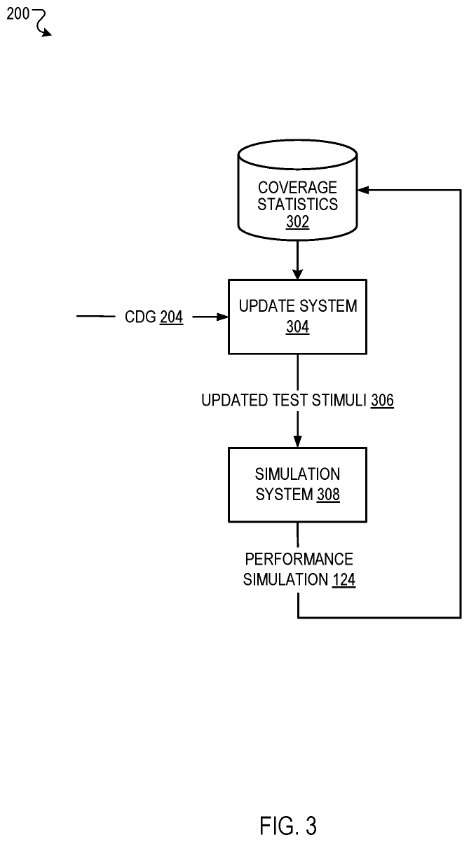

FIG. 3 shows a diagram of an example system 300 for generating updated test stimuli 306. The system 300 is an example of a system in which the systems, components, and techniques described below are implemented. For convenience, the system 300 will be described as being implemented by a system of one or more computers located in one or more locations. For example, a system, e.g., the system 100 of FIG. 1, appropriately programmed in accordance with this specification, can implement the system 300.

The system 300 shows the operation of the system 200 to generate updated test stimuli.

The system 300 generates test stimuli for testing the DUV. The system 300 performs operations related to testing the DUV over multiple simulation cycles.

The system 300 includes an update system 304 and a simulation system 308.

At each simulation cycle, the system 300 obtains a set of coverage statistics 302. The coverage statistics 302 summarize coverage reports (e.g., coverage reports 128) generated by the coverage analysis tool (e.g., coverage analysis tool 126). The coverage statistics 302 includes statistics of the different test-cases covered by the test stimuli. For example, the coverage statistics 302 can include statistics of code that was run to generate the random input stimuli and code that was used during the design simulation of the DUV. For example, the coverage statistics 302 can include how many times a segment of code was run as part of the performance simulation 124.

In this case, the code that was not run in the performance simulation can represent unexplored events (e.g., test-cases that were not tested) that can direct the next simulation of the DUV.

The coverage statistics 302 can be defined in terms of different covergroups associated with the different test-cases, as described in further detail with reference to FIG. 4.

The system 300 uses the update system 304 to generate updated test stimuli 306 based on the CDG 204 and the coverage statistics 302.

The update system 304 generates the updated test stimuli 306 by updating the weights of distribution constraints associated with one or more random variables. The distribution constraints are included in the constraints that the simulator uses to generate the test stimuli. The update system 304 uses the coverage statistics 302 and the CDG 204 to determine an updated coverage of the random variables, and the system 300 updates the weights of the distribution constraints based on the coverage, as described in further detail with reference to FIG. 4. The update system 304 then updates the test stimuli using the updated distribution constraints.

The system 300 then uses the simulation system 308 to simulate the performance of the DUV. The simulation system 308 processes the updated test stimuli 306 to generate a performance simulation 124. The performance simulation 124 includes information regarding the performance of the DUV based on the test-cases (e.g., covergroups) corresponding to the updated test stimuli 306.

The system 300 can then leverage the performance simulation 124 to update the coverage statistics 302 for the next simulation cycle.

All of the operations performed by system 300 are performed by the system 200 in FIG. 2.

FIG. 4 is a diagram showing operations performed by the system 200 to generate a CDG to update test stimuli. For convenience, the system 400 will be described as being performed by a system of one or more computers located in one or more locations. For example, a system, e.g., the system 100 of FIG. 1, appropriately programmed in accordance with this specification, can implement the system 400

The system 400 includes functional coverage 118 and the CDG 204. The functional coverage 118 includes an example of a covergroup 402 defined in Verilog. Covergroups 402 represent test-cases included in the verification plan that must be “covered” by the test stimuli.

In this example, the covergroup 402 is cg_memory. Cg_memory is sampled at every positive edge of a clock. Each covergroup contains at least one coverpoint that is defined over a value of each of the random variables 116. In this example, state_cp is a coverpoint 404 in cg_memory that depends on the value of the random variable State.

Additionally, the function coverage 118 defines the covergroup 402 and coverpoint 404 using coverbins 406. The coverbins 406 specify test-cases that the test stimuli aim to target. In this example, the coverbins 406 are valid_states, valid_trans, and reset_trans.

The CDG 204 is a mapping of the functional coverage 118 that includes random variable 116, covergroup 402, coverpoint 404, coverbins 406, and coveritems 408. Coveritems 408 are the values of the random variables 116 required to be tested in a simulation.

The system extracts the CDG 204 from functional coverage 118 to update the weights of distribution constraints 208.

The design parser 202 extracts the CDG 204 using the functional coverage 118 from the test bench 102. The design parser 202 can use a tool (e.g., the Verific System Verilog parser tool) to query the test bench 102 for the functional coverage 118 and to automatically extract the CDG 204.

To generate the CDG 204, the system 400 determines dependencies between the covergroup 402 and a random variable 116 from the functional coverage 118. The system 400 back traces from each coverpoint 404 in a covergroup 402 until the system 400 reaches a random variable 116. For each coverbin, 406, the system 400 assigns one or more coveritems 408 that must be tested in the performance simulation. Directed edges (shown by arrows) between the coveritems 408 enforce the ordering of the values of the coveritems 408 to be observed in the performance simulation.

The system 400 then updates the respective distribution constraints for one or more random variables 116 by identifying the “uncovered” coverpoints and updating the weights of the distribution constraints, which directs the constraint solver to generate test stimuli that target the “uncovered” coverpoints 404.

To identify one or more “uncovered” coverpoints 404 in the CDG 204, for each coverpoint 404, the system 400 determines a set of random variables 116 that relate to the coverpoint 404 and a set of coveritem nodes (e.g., coveritems 408) for each random variable 116. For each coveritem 408 and each corresponding random variable 116, the system 400 determines whether to update a weight assigned to the coveritem 408 in the distribution constraints based on whether the coveritem 408 is “covered” according to the coverage statistics.

In this example, coverbin valid_states illustrates the case in which all possible values for the random variable State have been tested (e.g., are covered in the coverage statistics). Coverbin valid_trans illustrates the case in which a particular sequence of State values, such as idle, have been tested, but the rest of the sequences of State values have not been tested. Coverbin reset_trans illustrates the case in which multiple sequences of State values, but not all State values, have been tested.

The system 400 determines that a coverbin 406 is “covered” only when all of the coveritems 408 associated with the coverbin 406 are tested. Thus, in this example, valid_trans and reset_trans are “uncovered.” Similarly, the system 400 may determine that a coverpoint 404 is “covered” only when all of the coveritems 408 associated with the coverpoint 404 are tested. This may reduce traversal times taken to find “uncovered” coverpoints 404 when more coverpoints 404 become determined as “covered.” The system 400 then determines whether to update the weights of the distribution constraints based on the “uncovered” coveritems 408.

If the system 400 determines to update the weight, the system 400 increases the weight assigned to the uncovered coveritem 408 in the distribution constraints for the random variable. Increasing the weight of the distribution constraint adaptively increases the possibility that the uncovered coveritem 408 will be tested in the next simulation.

The system 400 determines the weights of the distribution constraints by using MLE, as shown below in Equation 1:

$${θ}_{MLE} = arg {max}_{θ} P ( x ; θ ) \qquad ( 1 )$$

In this example, θ_{MLE} represents a distribution over multiple values of multiple random variables 116 that maximizes the likelihood of occurrence of x, which represents an observation set that includes certain coveritems 408. The certain coveritems 408 included in the observation set x are coveritems that were uncovered in the last simulation. Additionally, P(x;θ) represents the probability that the overall coverage of the design verification is increased, e.g., by increasing the coverage of x, the uncovered coveritems 408, in the distribution θ_{MLE}.

For example, for each random variable 116, the system 400 counts the number of times that the uncovered coveritems 408 have not been tested. For the next simulation, the system 400 increases the weight of the distribution constraint proportionally to the number of times that the uncovered coveritems 408 of the respective coverpoint 404 have not been tested. By adaptively increasing the weight of the distribution constraint, the system 400 uses MLE to generate an updated distribution OMLE over the values of the random variable 116 that maximizes the likelihood of the occurrence of the uncovered coverpoints 404 in the testing stimuli.

The system 400 then provides the updated distribution constraints to the simulator to update the test stimuli. The constraint solver generates the updated test stimuli based on the constraints, including the updated distribution constraints. The simulator then verifies the DUV using the updated test stimuli.

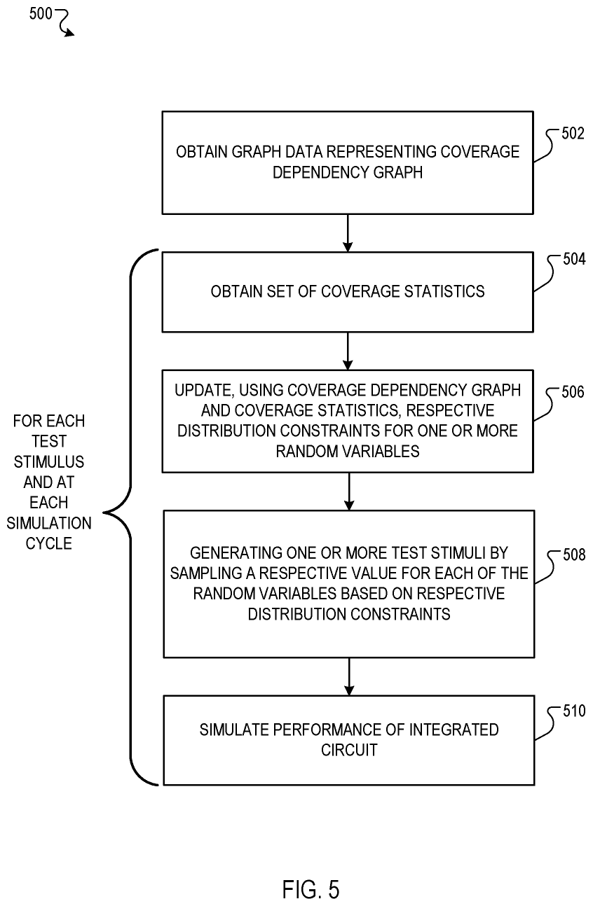

FIG. 5 is a flow diagram of an example process 500 for adaptively updating test stimuli to test a hardware design of an integrated circuit. For convenience, the process 500 will be described as being performed by a system of one or more computers located in one or more locations. For example, a system, e.g., the system 100 of FIG. 1, appropriately programmed in accordance with this specification, can perform the process 500.

The system can repeatedly perform iterations of the process 500 to repeatedly update the coverage statistics of the integrated circuit to generate test stimuli until a termination criterion has been satisfied, e.g., until a threshold number of iterations of the process 500 have been performed, until threshold amount of wall clock time has elapsed, or until the values of the coverage statistics have converged.

The system obtains graph data that represents the CDG to use for multiple simulation cycles (502). The CDG is derived from the functional coverage included in the test bench.

At each simulation cycle, the system obtains a set of coverage statistics (504). For example, in a simulation cycle, the system can perform a simulation, and the system can update the coverage statistics derived from the simulation to use for the next simulation cycle.

The system then updates, using the coverage dependency graph and coverage statistics, respective distribution constraints for one or more random variables. The distribution constraints are included in the constraints associated with the random variables (506). The system updates the respective distribution constraints by identifying the uncovered coveritems of the respective coverpoints.

The system generates one or more test stimuli by sampling a respective value for each of the random variables based on the respective distribution constraints (508). The system uses the updated distribution constraints to generate the test stimuli.

The system then simulates the performance of the integrated circuit (e.g., the DUV) using the one or more test stimuli to run the simulation (510).

This specification uses the term “configured” in connection with systems and computer program components. For a system of one or more computers to be configured to perform particular operations or actions means that the system has installed on it software, firmware, hardware, or a combination of them that in operation cause the system to perform the operations or actions. For one or more computer programs to be configured to perform particular operations or actions means that the one or more programs include instructions that, when executed by data processing apparatus, cause the apparatus to perform the operations or actions.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non-transitory storage medium for execution by, or to control the operation of, data processing apparatus. The computer storage medium can be a machine-readable storage device, a machine-readable storage substrate, a random or serial access memory device, or a combination of one or more of them. Alternatively or in addition, the program instructions can be encoded on an artificially-generated propagated signal, e.g., a machine-generated electrical, optical, or electromagnetic signal, that is generated to encode information for transmission to suitable receiver apparatus for execution by a data processing apparatus.

The term “data processing apparatus” refers to data processing hardware and encompasses all kinds of apparatus, devices, and machines for processing data, including by way of example a programmable processor, a computer, or multiple processors or computers. The apparatus can also be, or further include, special purpose logic circuitry, e.g., an FPGA (field programmable gate array) or an ASIC (application-specific integrated circuit). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, an app, a module, a software module, a script, or code, can be written in any form of programming language, including compiled or interpreted languages, or declarative or procedural languages; and it can be deployed in any form, including as a stand-alone program or as a module, component, subroutine, or other unit suitable for use in a computing environment. A program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a data communication network.

In this specification the term “engine” is used broadly to refer to a software-based system, subsystem, or process that is programmed to perform one or more specific functions. Generally, an engine will be implemented as one or more software modules or components, installed on one or more computers in one or more locations. In some cases, one or more computers will be dedicated to a particular engine; in other cases, multiple engines can be installed and running on the same computer or computers.

The processes and logic flows described in this specification can be performed by one or more programmable computers executing one or more computer programs to perform functions by operating on input data and generating output. The processes and logic flows can also be performed by special purpose logic circuitry, e.g., an FPGA or an ASIC, or by a combination of special purpose logic circuitry and one or more programmed computers.

Computers suitable for the execution of a computer program can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. The central processing unit and the memory can be supplemented by, or incorporated in, special purpose logic circuitry. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's device in response to requests received from the web browser. Also, a computer can interact with a user by sending text messages or other forms of message to a personal device, e.g., a smartphone that is running a messaging application, and receiving responsive messages from the user in return.

Data processing apparatus for implementing machine learning models can also include, for example, special-purpose hardware accelerator units for processing common and compute-intensive parts of machine learning training or production, i.e., inference, workloads.

Machine learning models can be implemented and deployed using a machine learning framework, e.g., a TensorFlow framework.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface, a web browser, or an app through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN) and a wide area network (WAN), e.g., the Internet.

The computing system can include clients and servers. A client and server are generally remote from each other and typically interact through a communication network. The relationship of client and server arises by virtue of computer programs running on the respective computers and having a client-server relationship to each other. In some embodiments, a server transmits data, e.g., an HTML page, to a user device, e.g., for purposes of displaying data to and receiving user input from a user interacting with the device, which acts as a client. Data generated at the user device, e.g., a result of the user interaction, can be received at the server from the device.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A method performed by one or more computers, the method comprising:
obtaining graph data representing a coverage dependency graph associated with a hardware design for an integrated circuit; and
at each of a plurality of simulation cycles, performing operations comprising:
obtaining a set of coverage statistics as of the simulation cycle;
updating, using the coverage dependency graph and the coverage statistics, respective distribution constraints for one or more random variables in a set of random variables;
after the updating, generating one or more test stimuli by, for each test stimulus, sampling a respective value for each of the random variables in the set of random variables based on the respective distribution constraints; and
simulating a performance of the integrated circuit for each of the test stimuli.

2. The method of claim 1, wherein obtaining graph data representing a coverage dependency graph associated with a hardware design for an integrated circuit comprises:
extracting the coverage dependency graph from a testbench for design verification of the hardware design.

3. The method of claim 1, wherein updating, using the coverage dependency graph and the coverage statistics, respective distribution constraints for one or more random variables in a set of random variables comprises:
identifying one or more uncovered coverpoints in the coverage dependency graph;
for each uncovered coverpoint:
determining, using the graph data, a set of random variables that relate to the uncovered coverpoint and a set of coveritem nodes for each random variable; and for each coveritem node and for each random variable, determining whether to update a weight assigned to the coveritem node in the distribution constraints for the random variable based on whether the coveritem node is covered according to the coverage statistics.

4. The method of claim 3, wherein updating, using the coverage dependency graph and the coverage statistics, respective distribution constraints for one or more random variables in a set of random variables further comprises:
for each coveritem node and for each random variable, increasing a weight assigned to the coveritem node in the distribution constraints for the random variable based on determining that the coveritem node is not covered according to the coverage statistics.

5. The method of claim 1, further comprising:
after performing the plurality of simulation cycles, fabricating the integrated circuit according to the hardware design.

6. The method of claim 1, the operations further comprising:
updating the set of coverage statistics after performing the simulation cycle.

7. (canceled)

8. (canceled)

9. A system comprising one or more computers and one or more storage devices storing instructions that are operable, when executed by the one or more computers, to cause the one or more computers to perform operations comprising:
obtaining graph data representing a coverage dependency graph associated with a hardware design for an integrated circuit; and
at each of a plurality of simulation cycles, performing operations comprising:
obtaining a set of coverage statistics as of the simulation cycle;
updating, using the coverage dependency graph and the coverage statistics, respective distribution constraints for one or more random variables in a set of random variables;
after the updating, generating one or more test stimuli by, for each test stimulus, sampling a respective value for each of the random variables in the set of random variables based on the respective distribution constraints; and
simulating a performance of the integrated circuit for each of the test stimuli.

10. The system of claim 9, wherein obtaining graph data representing a coverage dependency graph associated with a hardware design for an integrated circuit comprises:
extracting the coverage dependency graph from a testbench for design verification of the hardware design.

11. The system of claim 9, wherein updating, using the coverage dependency graph and the coverage statistics, respective distribution constraints for one or more random variables in a set of random variables comprises:
identifying one or more uncovered coverpoints in the coverage dependency graph;
for each uncovered coverpoint:
determining, using the graph data, a set of random variables that relate to the uncovered coverpoint and a set of coveritem nodes for each random variable; and for each coveritem node and for each random variable, determining whether to update a weight assigned to the coveritem node in the distribution constraints for the random variable based on whether the coveritem node is covered according to the coverage statistics.

12. The system of claim 11, wherein updating, using the coverage dependency graph and the coverage statistics, respective distribution constraints for one or more random variables in a set of random variables further comprises:
for each coveritem node and for each random variable, increasing a weight assigned to the coveritem node in the distribution constraints for the random variable based on determining that the coveritem node is not covered according to the coverage statistics.

13. The system of claim 9, further comprising:
after performing the plurality of simulation cycles, fabricating the integrated circuit according to the hardware design.

14. The system of claim 9, the operations further comprising:
updating the set of coverage statistics after performing the simulation cycle.

15. One or more non-transitory computer storage media encoded with instructions that, when executed by one or more computers, cause the one or more computers to perform operations comprising:
obtaining graph data representing a coverage dependency graph associated with a hardware design for an integrated circuit; and
at each of a plurality of simulation cycles, performing operations comprising:
obtaining a set of coverage statistics as of the simulation cycle;
updating, using the coverage dependency graph and the coverage statistics, respective distribution constraints for one or more random variables in a set of random variables;
after the updating, generating one or more test stimuli by, for each test stimulus, sampling a respective value for each of the random variables in the set of random variables based on the respective distribution constraints; and
simulating a performance of the integrated circuit for each of the test stimuli.

16. The non-transitory computer storage media of claim 15, wherein obtaining graph data representing a coverage dependency graph associated with a hardware design for an integrated circuit comprises:
extracting the coverage dependency graph from a testbench for design verification of the hardware design.

17. The non-transitory computer storage media of claim 15, wherein updating, using the coverage dependency graph and the coverage statistics, respective distribution constraints for one or more random variables in a set of random variables comprises:
identifying one or more uncovered coverpoints in the coverage dependency graph;
for each uncovered coverpoint:
determining, using the graph data, a set of random variables that relate to the uncovered coverpoint and a set of coveritem nodes for each random variable; and for each coveritem node and for each random variable, determining whether to update a weight assigned to the coveritem node in the distribution constraints for the random variable based on whether the coveritem node is covered according to the coverage statistics.

18. The non-transitory computer storage media of claim 17, wherein updating, using the coverage dependency graph and the coverage statistics, respective distribution constraints for one or more random variables in a set of random variables further comprises:
for each coveritem node and for each random variable, increasing a weight assigned to the coveritem node in the distribution constraints for the random variable based on determining that the coveritem node is not covered according to the coverage statistics.

19. The non-transitory computer storage media of claim 15, further comprising:
after performing the plurality of simulation cycles, fabricating the integrated circuit according to the hardware design.

20. The non-transitory computer storage media of claim 15, the operations further comprising:
updating the set of coverage statistics after performing the simulation cycle.
